(19) United States
(12) Patent Application Publication
(10) Pub. No.: US 2016/0120024 A1
(43) Pub. Date: Apr. 28, 2016

(54) Linear Conductor Connection Terminal

(71) Applicant: IRISO ELECTRONICS CO., LTD., Kanagawa (JP)

(72) Inventor: Jun Oguro, Kanagawa (JP)

(73) Assignee: IRISO ELECTRONICS CO., LTD., Kanagawa (JP)

(21) Appl. No.: 14/881,567

(22) Filed: Oct. 13, 2015

(30) Foreign Application Priority Data
Oct. 15, 2014 (JP) 2014-210696

(51) Int. Cl. H05K 1/02; H01R 4/48; H01R 12/55

(52) U.S. Cl. CPC H05K 1/0213; H01R 12/55; H01R 4/48; H05K 2201/10189; H05K 2201/10287

(57) ABSTRACT

A linear conductor connection terminal that is fixed to a substrate and that comes in contact in a conductive manner with a linear conductor that is inserted in a hole portion provided in the substrate. The linear conductor connection terminal includes a contact portion that is positioned inside the hole portion and that comes in contact in the hole portion with the linear conductor in a conductive manner; an elastic piece that elastically supports the contact portion; a top surface portion provided so as to be spaced apart from the contact portion in an insertion direction of the linear conductor, the top surface portion including an insertion hole to introduce the linear conductor to the contact portion; and a first leg portion and a second leg portion that support the top surface portion that is spaced apart from the contact portion.

### BACKGROUND OF THE INVENTION

1. Field of the Invention

The present disclosure relates to a linear conductor connection terminal that conductively connects a substrate and a linear conductor, such as a cable, to each other.

2. Description of the Related Art

A typical method of fixing a linear conductor such as a cable to a substrate is to insert the linear conductor into a through hole provided in the substrate and solder the linear conductor. However, particularly in a case in which the cable is thin and in a case in which other components are densely mounted around the fixing position, fixing with soldering requires high skills such that it is difficult to increase work efficiency.

Accordingly, in recent years, a linear conductor connection terminal that is fixed to a surface of the substrate and that conductively connects the linear conductor and the substrate to each other is used. As such a linear conductor connection terminal, there is a linear conductor connection terminal including an insertion hole of the linear conductor, a housing disposed on the substrate surface, and a contact portion housed in the housing (Japanese Registered Utility Model No. 3069754, for example). In such a linear conductor connection terminal configured in the above manner, since the linear conductor and the contact portion are made to be in contact with each other in a conductive manner inside the housing, the contact portion can be protected from foreign matters, such as dust, and obstacles with the housing.

However, in the configuration described above that includes the housing that houses the contact portion and in which the contact portion and the linear conductor come in contact in a conductive manner inside the housing, the terminal becomes large by the amount of the housing. Accordingly, it is difficult to reduce the size of the linear conductor connection terminal, and in a case in which the linear conductor and the substrate are conductively connected to each other with a linear conductor connection terminal, a space that is larger than the space in the case of soldering is disadvantageously required.

The present disclosure has been made to overcome the above disadvantages. In other words, an object is to provide, with high work efficiency, a small-sized linear conductor connection terminal.

### SUMMARY OF THE INVENTION

In order to achieve the above object, the present disclosure is configured in the following manner.

In other words, the present disclosure provides a linear conductor connection terminal that is fixed to a substrate and that comes in contact in a conductive manner with a linear conductor that is inserted in a hole portion provided in the substrate. The linear conductor connection terminal includes a contact portion that is positioned inside the hole portion and that comes in contact in the hole portion with the linear conductor in a conductive manner; an elastic piece that elastically supports the contact portion; a top surface portion provided so as to be spaced apart from the contact portion in an insertion direction of the linear conductor, the top surface portion including an insertion hole to introduce the linear conductor to the contact portion; and a leg portion that supports the top surface portion that is spaced apart from the contact portion.

By merely introducing the linear conductor into the contact portion through the insertion hole, the present disclosure can conductively connect the linear conductor and the substrate to each other. Accordingly, compared with a method in which a linear conductor is fixed to a substrate by soldering, the work of conductively connecting the linear conductor and the substrate to each other can be performed efficiently.

Furthermore, the present disclosure is a substrate connection terminal that comes in contact in a conductive manner with the linear conductor that is inserted into the hole portion provided in the substrate and includes a contact portion that is positioned inside the hole portion and that comes in contact in a conductive manner with the linear conductor inside the hole portion and an elastic piece that elastically supports the contact portion. With the above, compared with a case in which the contact portion is positioned on the substrate surface and is in contact with the linear conductor in a conductive manner, the linear conductor connection terminal can be reduced in size in the height direction.

Furthermore, the present disclosure includes the top surface portion provided so as to be spaced apart from the contact portion in the insertion direction of the linear conductor, the top surface portion including an insertion hole to introduce the linear conductor to the contact portion; and the leg portion that supports the top surface portion that is spaced apart from the contact portion. Accordingly, the linear conductor can be held between the insertion hole and the contact portion that are provided so as to be spaced apart from each other, and the linear conductor can be held at two points that are sufficiently apart from each other such that the linear conductor can be prevented from collapsing in a direction parallel to the substrate and can be held in an upright state with respect to the substrate. With the above, an area of the substrate surface occupied by the linear conductor can be made small; accordingly, even at portions where the components are mounted in a dense manner, the linear conductor can be fixed easily.

In the present disclosure, the contact portion may include a first contact portion and a second contact portion that oppose each other, the elastic piece may include a first elastic piece that elastically supports the first contact portion, and a second elastic piece that elastically supports the second contact portion, and the first contact portion and the second contact portion may press and pinch the linear conductor that is inserted between the first contact portion and the second contact portion with spring force of the first elastic piece and the second elastic piece so as to be in contact with the linear conductor in a conductive manner.

With the above, the linear conductor can be pressed and pinched from two different directions with the two contact portions. Accordingly, contact with the linear conductor in a conductive manner can be made in a reliable manner.

Furthermore, the elastic pieces may each be formed of a metal plate, and the first contact portion and the second contact portion may be edge portions of the metal plates configuring the elastic pieces and may be made to bite into and press and pinch the linear conductor such that the linear conductor can be reliably prevented from being pulled out.

In the present disclosure, the elastic piece may include a plate surface that extends in the insertion direction of the linear conductor and may include a guide portion that guides the linear conductor to the contact portion. With the above, the linear conductor can reach the contact portion easily and the operation efficiency of making contact in a conductive manner can be improved.

According to the present disclosure, a small-sized linear conductor connection terminal can be provided with high work efficiency.

### BRIEF DESCRIPTION OF THE DRAWINGS

FIG. 1 is a perspective view of a linear conductor connection terminal of a first exemplary embodiment.

FIG. 2 is a front view of the linear conductor connection terminal in FIG. 1.

FIG. 3 is a plan view of the linear conductor connection terminal in FIG. 1.

FIG. 4 is a bottom view of the linear conductor connection terminal in FIG. 1.

FIG. 5 is a right side view of the linear conductor connection terminal in FIG. 1.

FIG. 6 is a development of the linear conductor connection terminal in FIG. 1.

FIG. 7 is a bottom view illustrating a state in which the linear conductor connection terminal in FIG. 1 is in contact with a linear conductor in a conductive manner.

FIG. 8 is a cross-sectional view illustrating a state in which the linear conductor connection terminal in FIG. 1 is fixed to the substrate and is in contact with the linear conductor in a conductive manner.

FIG. 9 is a perspective view of a linear conductor connection terminal of a second exemplary embodiment.

FIG. 10 is a front view of the linear conductor connection terminal in FIG. 9.

FIG. 11 is a plan view of the linear conductor connection terminal in FIG. 9.

FIG. 12 is a bottom view of the linear conductor connection terminal in FIG. 9.

FIG. 13 is a right side view of the linear conductor connection terminal in FIG. 9.

FIG. 14 is a development of the linear conductor connection terminal in FIG. 9.

FIG. 15 is a bottom view illustrating a state in which the linear conductor connection terminal illustrated in FIG. 9 is in contact with a linear conductor in a conductive manner.

FIG. 16 is a cross-sectional view illustrating a state in which the linear conductor connection terminal in FIG. 9 is fixed to the substrate and is in contact with the linear conductor in a conductive manner.

### DESCRIPTION OF THE PREFERRED EMBODIMENTS

Hereinafter, exemplary embodiments of linear conductor connection terminals 1 and 11 will be described with reference to the drawings. Note that the linear conductor connection terminals 1 and 11 are each, for example, mounted on a substrate 3 and are each used to conductively connect the substrate 3 to a linear conductor 2a of a cable 2.

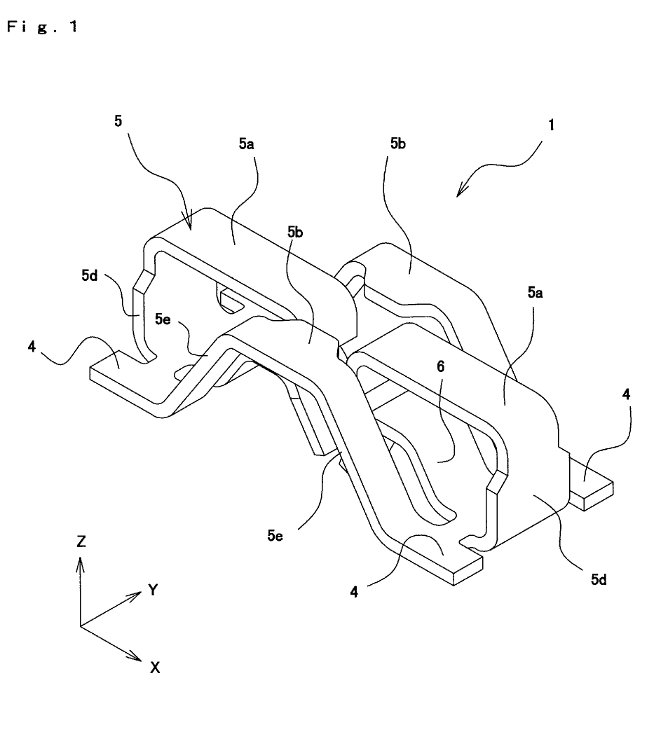

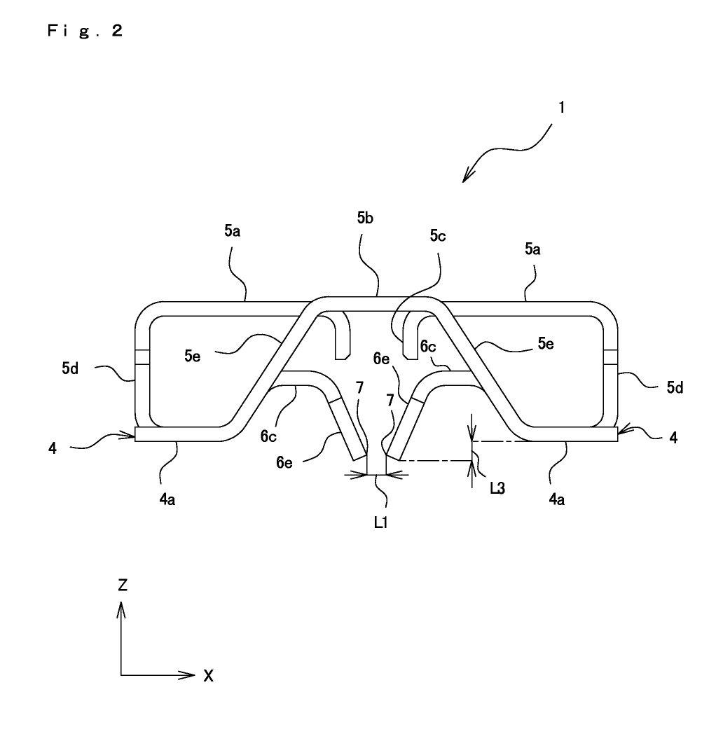

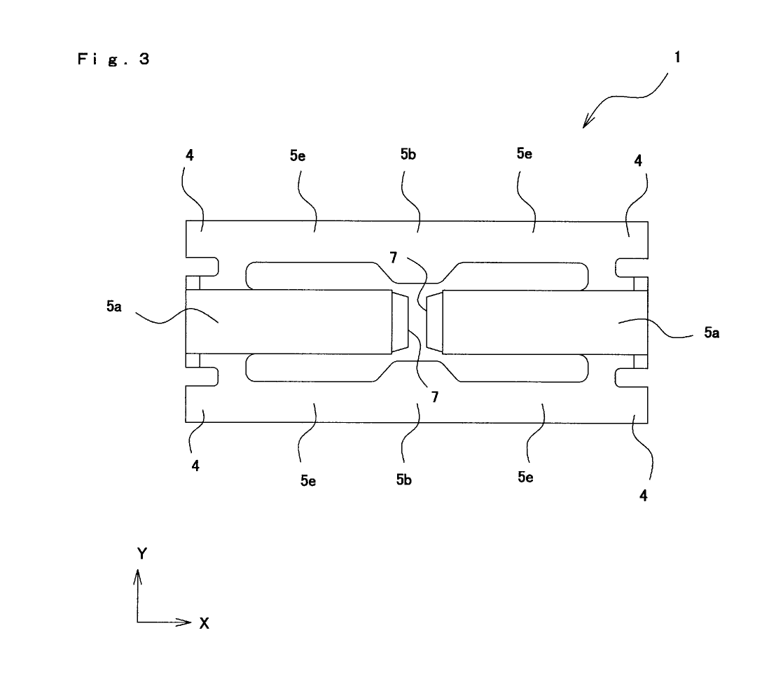

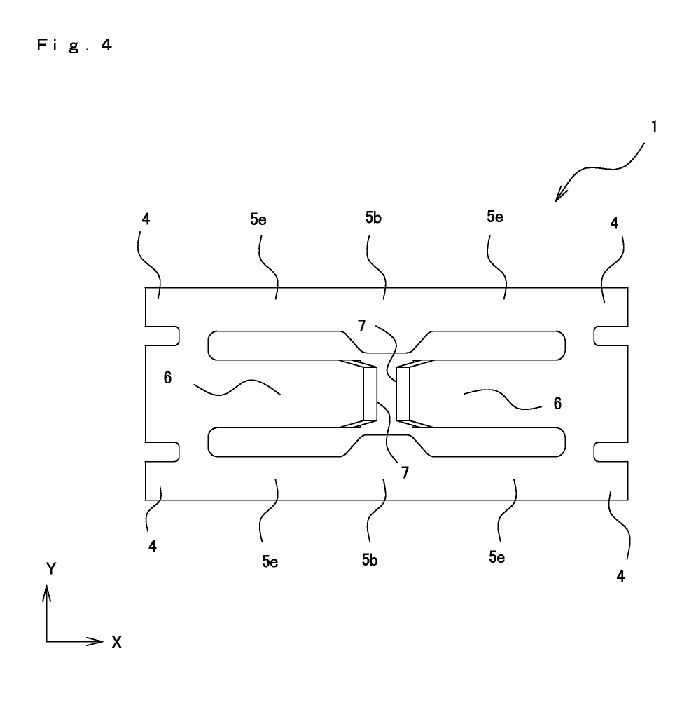

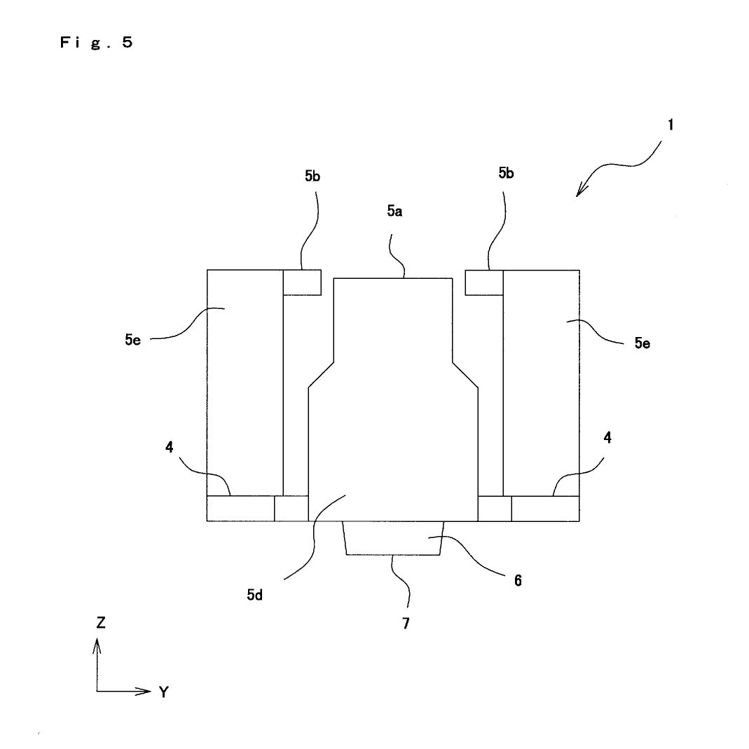

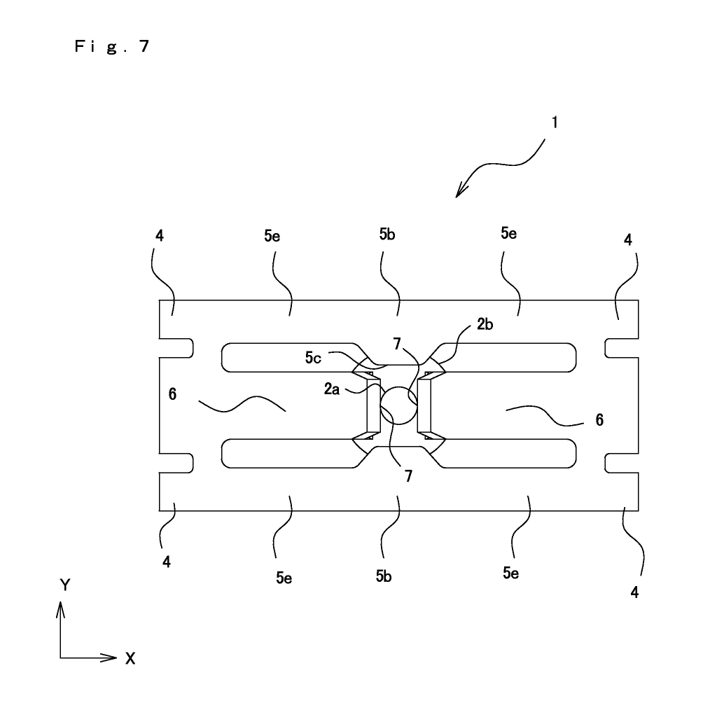

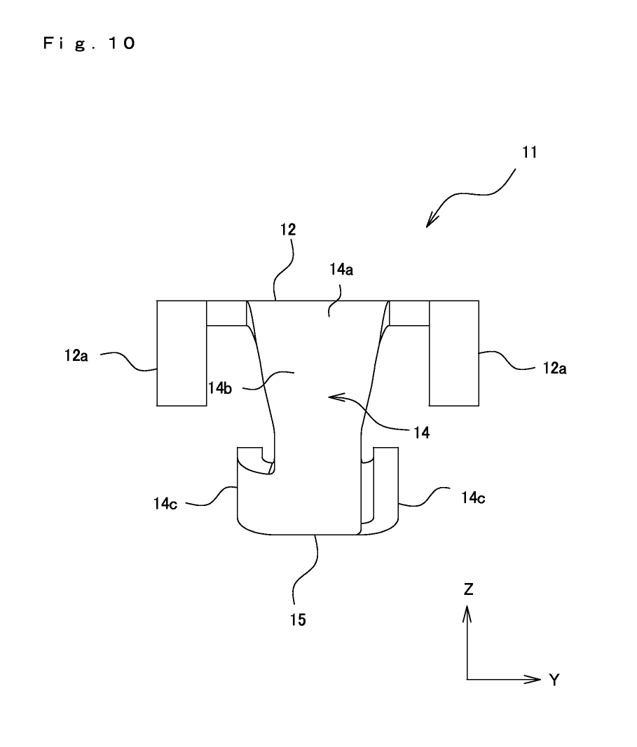

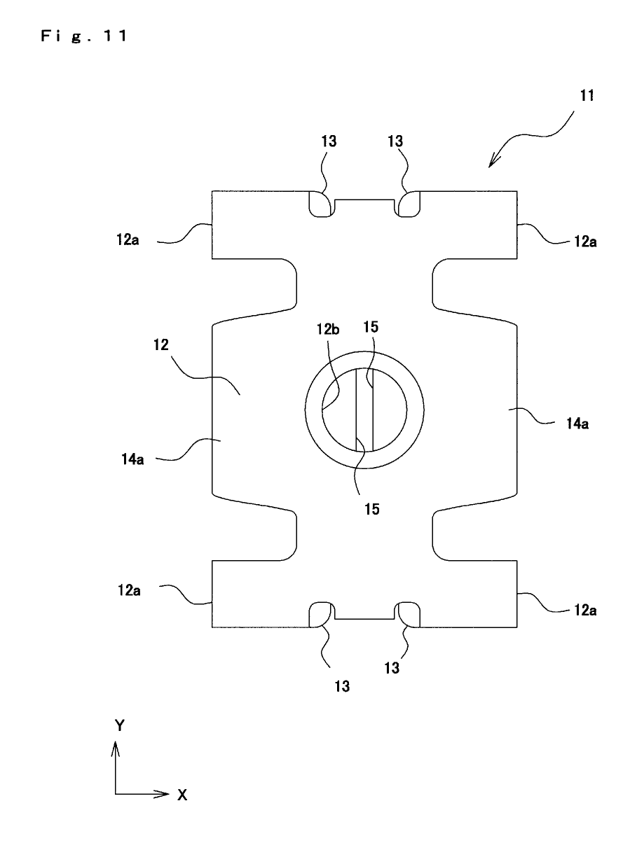

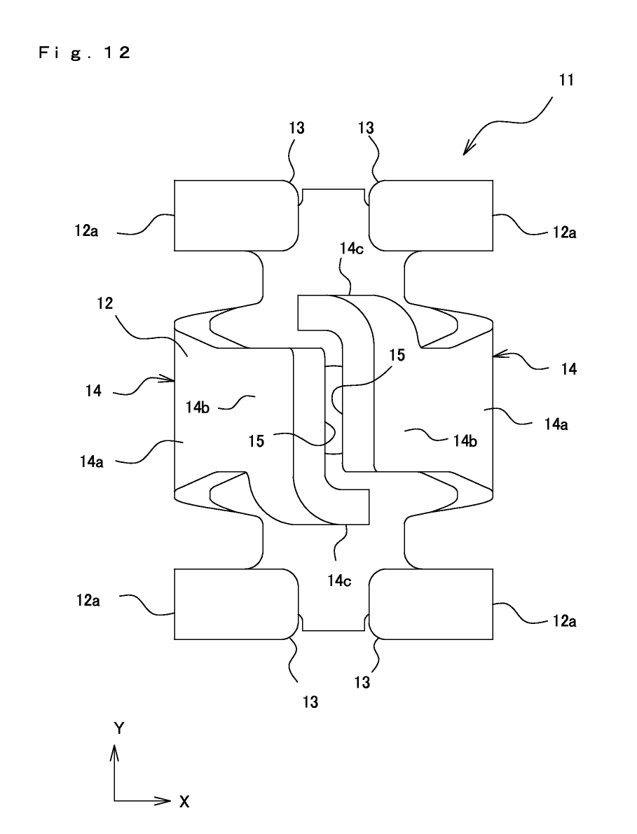

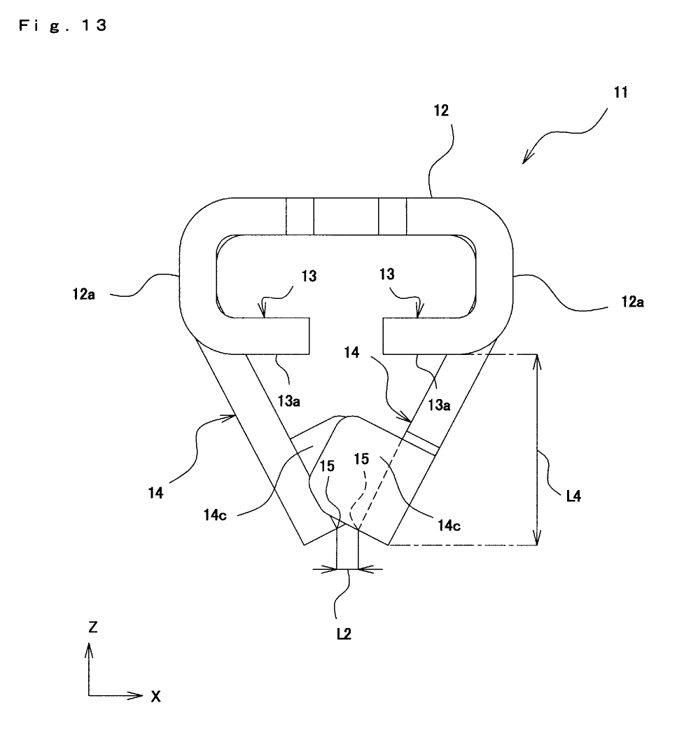

As illustrated in FIGS. 1 to 16, in the description, the claims, and the drawings, the left-right direction is an X direction, the height direction (the up-down direction) of the linear conductor connection terminals 1 and 11 is a Z direction, and the front-rear direction that is orthogonal to both the X direction and the Z direction is a Y direction. Furthermore, the linear conductor 2a is inserted in the height direction Z through the linear conductor connection terminal 1 or 11 and a hole portion 3b included in the substrate 3. In the height direction Z, the near side of the linear conductor connection terminals 1 and 11 with respect to the insertion direction of the linear conductor 2a is the upper side and, conversely, the far side with respect to the insertion direction is the lower side. Note that the up-down, the left-right, and the front-rear directions in the description do not limit the directions in which the linear conductor connection terminals 1 and 11 of the present disclosure are mounted and used.

Since the rear views of the linear conductor connection terminals 1 and 11 are illustrated in a similar manner to the front views, descriptions thereof are omitted. Furthermore, since the left-side views of the linear conductor connection terminals 1 and 11 are illustrated in a similar manner to the right-side views, descriptions thereof are omitted as well.

### First Exemplary Embodiment

### FIGS. 1 to 8

In the present exemplary embodiment, the X direction is the longitudinal direction of the linear conductor connection terminal 1, and the Y direction corresponds to the short direction.

The linear conductor connection terminal 1 of the present exemplary embodiment is a metal terminal that, for example, conductively connects the cable 2 that includes the linear conductor 2a and an electrically insulating coating 2b, and the substrate 3 to each other. As illustrated in FIGS. 1 to 6, the linear conductor connection terminal 1 includes fixed portions 4 that are fixed to the substrate 3, a top surface portion 5, elastic pieces 6, and contact portions 7. Furthermore, the linear conductor connection terminal 1 is formed by bending a single piece of conductive metal plate formed by punching.

### Fixed Portion

As illustrated in FIGS. 1 to 5, the fixed portions 4 are formed on both end sides of the linear conductor connection terminal 1 in the left-right direction X. Furthermore, each of the fixed portions 4 has a plate surface that is parallel to a substrate surface 3a and is formed of a rectangular metal plate that extends in the front-rear direction Y. By fixing the fixed portions 4 by soldering, the linear conductor connection terminal 1 is fixed to the substrate 3.

### Top Surface Portion

The top surface portion 5 is provided so as to be spaced apart from the substrate surface 3a and, as illustrated in FIGS. 1 to 5, includes lateral pieces 5a, front-rear pieces 5b, and an insertion hole 5c.

The lateral pieces 5a are formed of thin metal shaft pieces that extend in the left-right direction X at substantially the middle of the linear conductor connection terminal 1 in the front-rear direction Y. Furthermore, a single pair of lateral pieces 5a are provided in the left-right direction X.

First leg portions 5d that extend in the height direction Z from the fixed portions 4 are connected to one end sides of the lateral pieces 5a, and the lateral pieces 5a are supported with the first leg portions 5d so as to be spaced apart from the substrate surface 3a.

The front-rear pieces 5b are formed of substantially rectangular metal pieces that extend in the left-right direction X at both end sides of the linear conductor connection terminal 1 in the front-rear direction Y. Furthermore, a single pair of front-rear pieces 5b are provided in the front-rear direction Y.

Second leg portions 5e and 5e that extend in an inclined manner with respect to the height direction Z from the fixed portions 4 are connected to both end sides of the front-rear pieces 5b in the left-right direction X, and the front-rear pieces 5b are supported with the second leg portions 5e and 5e so as to be spaced apart from the substrate surface 3a. The pair of second leg portions 5e and 5e that are connected to a single front-rear piece 5b are inclined from the fixed portions 4 side to the distal end side in a direction that approaches each other.

The insertion hole 5c is formed as a gap provided between the pair of lateral pieces 5a and 5a and between the pair of front-rear pieces 5b and 5b. Furthermore, the insertion hole 5c is provided above a first contact portion 7A and a second contact portion 7B described later that oppose each other.

The distal end sides of the lateral pieces 5a are bent downwards in the height direction Z and functions as a guide when inserting the linear conductor 2a into the insertion hole 5c.

Furthermore, the front-rear pieces 5b protrude towards the insertion hole 5c side.

By adjusting the space between the lateral pieces 5a and 5a and the space between the front-rear pieces 5b and 5b, the insertion hole 5c is set to a size that allows the linear conductor 2a of the cable 2 to be inserted therethrough but does not allow the coating 2b to be inserted therein.

As in the present exemplary embodiment, by forming the insertion hole 5c as a gap provided between the pair of lateral pieces 5a and 5a and between the pair of front-rear pieces 5b and 5b, the size of the insertion hole 5c can be easily adjusted in accordance with the diameter of the linear conductor 2a by adjusting the inclination of the first leg portions 5d and the second leg portions 5e and by adjusting the length of the lateral pieces 5a and 5a in the left-right direction X and the length of the front-rear pieces 5b and 5b in the front-rear direction Y.

The lateral pieces 5a are also supported with the first leg portions 5d so as to be spaced apart from the contact portions 7 described later in the height direction Z. Furthermore, the front-rear pieces 5b are also supported with the second leg portions 5e and 5e so as to be spaced apart from the contact portions 7 described later in the height direction Z. As described above, the insertion hole 5c formed by the lateral pieces 5a and 5a and the front-rear pieces 5b and 5b, and the contact portions 7 are spaced apart from each other such that an insertion passage 8 of the linear conductor 2a is formed between the insertion hole 5c and the contact portions 7.

### Elastic Piece

The elastic pieces 6 are formed by bending a narrow width metal piece and each single elastic piece 6 extends from the corresponding fixed portions 4 and 4. As illustrated in FIGS. 1, 2, and 8, the elastic pieces 6 are each formed in a substantially concave shape in cross-sectional view and have a plate thickness that is about the same as that of the lateral piece 5a. Furthermore, each of the elastic pieces 6 includes a first inclination portion 6a, a first bend portion 6b, a lateral piece 6c, a second bend portion 6d, a second inclination portion 6e, and a third bend portion 6f. A first elastic piece 6A and a second elastic piece 6B oppose each other.

Each first inclination portion 6a is connected to the corresponding first bend portion 6b described later and inclines and extends in an upward direction in the height direction Z and in a direction that approaches the linear conductor 2a when the linear conductor 2a is inserted in the linear conductor connection terminal 1.

Each first bend portion 6b is provided between the corresponding fixed portions 4 and the first inclination portion 6a.

Each lateral piece 6c is connected to the corresponding second bend portion 6d described later and extends in the left-right direction X and in a direction that approaches the linear conductor 2a when the linear conductor 2a is inserted in the linear conductor connection terminal 1.

Each second bend portion 6d is provided between the corresponding first inclination portion 6a and the corresponding lateral piece 6c.

Each second inclination portion 6e is connected to the corresponding third bend portion 6f described later and inclines in a downward direction in the height direction Z and in a direction that approaches the linear conductor 2a when the linear conductor 2a is inserted in the linear conductor connection terminal 1.

A lower end of each second inclination portion 6e is disposed below undersides 4a of the fixed portions 4 in the height direction Z.

The third bend portion 6f is provided between the lateral piece 6c and the second inclination portion 6e.

Mainly, the first bend portions 6b, the second bend portions 6d, and the third bend portions 6f elastically deform in the height direction Z and the left-right direction X. With the above, the elastic pieces 6 as a whole can be elastically deformed.

### Contact Portion

As illustrated in FIGS. 1 to 5, and 8, the contact portions 7 are provided on the distal end sides of the second inclination portions 6e of the elastic pieces 6. Furthermore, the contact portions 7 are provided at edge portions of the distal end sides of the metal pieces that constitute the first elastic piece 6A and the second elastic piece 6B. The first contact portion 7A and the second contact portion 7B that are provided in the first elastic piece 6A and the second elastic piece 6B, respectively, oppose each other.

As described above, the distal end sides of the second inclination portions 6e are disposed below the undersides 4a of the fixed portions 4 by a length of L3. Furthermore, the contact portions 7 that are provided on the distal end sides of the second inclination portions 6e are disposed below the undersides 4a of the fixed portions 4 by a length that is substantially the same as length L3. Moreover, the gap L1 between the first contact portion 7A and the second contact portion 7B that oppose each other is provided so as to be narrower than the diameter of the linear conductor 2a when the linear conductor 2a is not inserted in the linear conductor connection terminal 1.

As described above, the insertion passage 8 of the linear conductor 2a is formed between the gap L1 between the first contact portion 7A and the second contact portion 7B, and the insertion hole 5c.

### Description of Usage

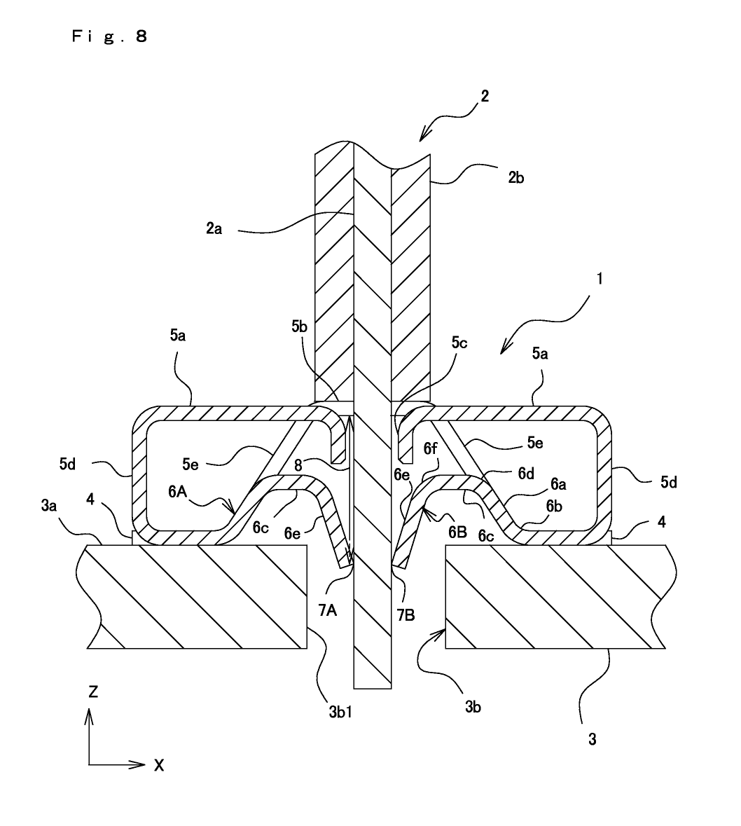

As illustrated in FIG. 8, the hole portion 3b that penetrates through the substrate 3 in the plate thickness direction is provided in the substrate 3.

Furthermore, as described above, the contact portions 7 are disposed below the undersides 4a of the fixed portions 4 of the linear conductor connection terminal 1 by a length that is substantially the same as length L3. The contact portions 7 are disposed inside the hole portion 3b provided in the substrate 3 and, in this state, the fixed portions 4 are soldered to the substrate surface 3a of the substrate 3. With the above, the linear conductor connection terminal 1 can be fixed to the substrate surface 3a.

The linear conductor 2a of the cable 2 is inserted into the insertion hole 5c positioned above the contact portions 7 in the height direction Z. By further inserting the linear conductor 2a towards the lower side in the height direction Z, a tip of the linear conductor 2a presses the first elastic piece 6A and the second elastic piece 6B towards the lower side. With the above, the first bend portions 6b to the third bend portions 6f of the elastic pieces 6 are elastically deformed and the elastic pieces 6 as a whole are elastically deformed. With the above, the gap L1 between the opposing first contact portion 7A and the second contact portion 7B is pushed and widened to about the same size as the diameter of the linear conductor 2a and, accordingly, the gap L1 allows the linear conductor 2a to pass therethrough.

By stopping the insertion operation of the linear conductor 2a, the contact portions 7 formed on the edge portions of the metal pieces constituting the elastic pieces 6 bites into the linear conductor 2a. By having the first contact portion 7A and the second contact portion 7B opposing each other bite into, and press and pinch the linear conductor 2a from both sides, the linear conductor 2a, the first contact portion 7A, and the second contact portion 7B are conductively connected in a reliable manner. In the above state, the linear conductor 2a is maintained in an upright state with respect to the substrate 3. As described above, by conductively connecting the linear conductor 2a to the substrate 3 while the linear conductor 2a is in an upright state, the space occupied by the linear conductor 2a on the substrate surface 3a can be reduced. Therefore, even if there is a portion on which the components are mounted densely, the linear conductor 2a can be made to be in contact in a conductive manner with the substrate 3 in a readily manner.

Furthermore, as described above, the insertion hole 5c is provided with a size that allows the linear conductor 2a of the cable 2 to be inserted therethrough but does not allow the coating 2b to be inserted therein. Accordingly, even if the linear conductor 2a is inserted into the insertion hole 5c, the insertion is stopped when the coating 2b abuts against the upper side (the upper surfaces of the lateral pieces 5a and the front-rear pieces 5b) of the insertion hole 5c. By adjusting the length in which the linear conductor 2a is exposed from the coating 2b, the length in which the linear conductor 2a is inserted into the hole portion 3b of the substrate 3 can be adjusted.

After completion of the operation of having the linear conductor 2a be in contact with the linear conductor connection terminal 1 in a conductive manner, even if the cable 2 is pulled in the pulling-out direction, the contact portions 7 provided at the edge portions of the metal plates constituting the elastic pieces 6 bite into the linear conductor 2a. In the above manner, the linear conductor 2a can be reliably prevented from being pulled out.

As described above, without performing any soldering, by mere insertion of the linear conductor 2a into the insertion hole 5c, the linear conductor 2a can be made to be in contact with the contact portions 7 in a conductive manner and the work of conductively connecting the linear conductor 2a to the substrate 3 can be completed in a readily manner.

Note that the tip portion of the linear conductor 2a may protrude out from below the substrate 3 while the linear conductor 2a is in contact with the linear conductor connection terminal 1 in a conductive manner. The above can be achieved by having the length of the portion of the linear conductor 2a that is exposed from the distal end of the coating 2b to be longer than the length from the insertion hole 5c to the surface on the lower side of the substrate 3 while in a state in which the linear conductor connection terminal 1 is mounted on the substrate surface 3a. By increasing the length of the protrusion in the above manner, visual recognition of the completion of the operation having the linear conductor 2a be in contact with the linear conductor connection terminal 1 in a conductive manner can be facilitated. Furthermore, with the above, the length in which the tip of the linear conductor 2a protruding downwards from the contact portions 7 can be made longer. Accordingly, prevention of the linear conductor 2a from being pulled out from the linear conductor connection terminal 1 can be facilitated and connection reliability can be increased.

### Achieving Both Reduction in Size and Connection Reliability

In the present exemplary embodiment, the plate thickness of the substrate 3 is about 1.2 mm and the diameter of the linear conductor 2a is about 0.64 mm. Furthermore, the length of the entire linear conductor connection terminal 1 in the left-right direction X is about 5.0 mm, the length in the front-rear direction Y is about 2.2 mm, and the length in the height direction Z is about 1.7 mm. Accordingly, the linear conductor connection terminal 1 can be reduced to a size that is about the same as the amount of solder remaining on the substrate surface 3a when fixing the linear conductor 2a to the substrate 3 by soldering, for example.

A height from the undersides 4a of the fixed portions 4 to an upper portion of the insertion hole 5c (upper ends of the lateral pieces 5a and the front-rear pieces 5b), in other words, a length of a structure portion on an upper side that is disposed above the substrate surface 3a in the height direction Z is about 1.5 mm. Furthermore, a length from the undersides 4a of the fixed portions 4 to the distal ends of the elastic pieces 6 in the height direction Z, in other words, a length L2 of a structure portion on a lower side in the height direction Z that protrudes downwards from the undersides 4a of the fixed portions 4 and that is inserted into the hole portion 3b of the substrate 3 is about 0.2 mm and is smaller than the plate thickness of the substrate 3.

By configuring the distance between the insertion hole 5c and the contact portions 7 to be about 1.7 mm, the linear conductor 2a can be held at two points that are sufficiently set apart from each other. With the above, it is easier to hold the linear conductor 2a in an upright state with respect to the substrate 3 without the linear conductor 2a collapsing in a direction parallel to the substrate 3. Accordingly, the space occupied by the linear conductor 2a on the substrate surface 3a can be made small.

The linear conductor connection terminal 1 is fixed to the substrate 3 while in the state in which the contact portions 7 and the elastic pieces 6 are inserted about 0.2 mm into the hole portion 3b of the substrate 3. If supposedly, the contact portions 7 are provided on the substrate 3, then in order to set the insertion hole 5c sufficiently apart from the contact portions 7, the insertion hole 5c needs to be provided at a position that is farther away from the substrate surface 3a. Accordingly, the size of the structure portion of the linear conductor connection terminal 1 on the upper side that is disposed on the upper side of the substrate 3 becomes disadvantageously large in the height direction Z. Accordingly, in the present exemplary embodiment, as described above, the contact portions 7 are disposed inside the hole portion 3b that is provided in the substrate 3 and are made to be in contact with the linear conductor 2a in a conductive manner at portions inside the hole portion 3b. By doing so, while the insertion hole 5c and the contact portions 7 can be sufficiently set apart from each other, in the linear conductor connection terminal 1, the size of the structure portion on the upper side in the height direction Z that is disposed on the upper side of the substrate 3 can be reduced by the length in which the contact portions 7 are disposed below the undersides 4a of the fixed portions 4 (by substantially the same length as length L4).

Furthermore, if supposedly, the contact portions 7 protrude below the substrate 3 and are in contact with the linear conductor 2a in a conductive manner below the substrate 3, then, situations such as the contact portions 7 being separated from the linear conductor due to an impact caused by an obstacle coming into contact with the portion in contact or a contact failure occurring by adhesion of foreign matters such as dust and dirt in the portion in contact easily occur. Conversely, as in the present exemplary embodiment, by having the contact portions 7 and the linear conductor 2a be in contact with each other inside the hole portion 3b in a conductive manner, the portion in contact can be protected by an inner wall 3b1 forming the hole portion 3b. Accordingly, the contact reliability of the linear conductor connection terminal 1 can be increased.

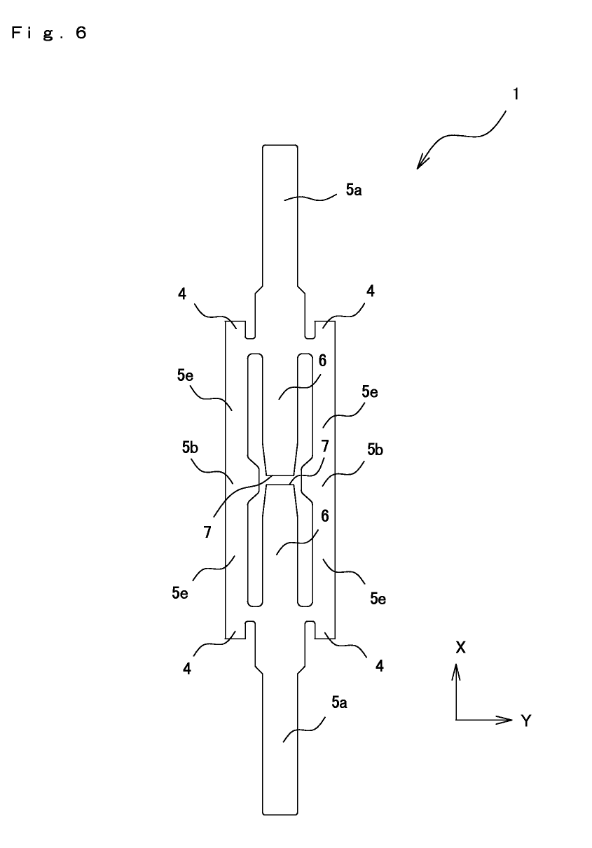

As illustrated in FIG. 6, when the linear conductor connection terminal 1 is expanded, the front-rear pieces 5b of the top surface portion 5 are disposed at substantially the middle in the left-right direction X and on both end sides in the front-rear direction Y. The fixed portions 4 are provided at both end sides of the front-rear pieces 5b in the left-right direction X. The lateral pieces 5a of the top surface portion 5 extend in the left-right direction X towards the outside from the fixed portions 4. Accordingly, since the lateral pieces 5a are not disposed in a restricted space when the linear conductor connection terminal 1 is in the expanded state, the length of the lateral pieces 5a can be designed freely. Accordingly, the size of the insertion hole 5c can be changed freely in accordance with the diameter of the linear conductor 2a by providing the lateral pieces 5a with a long or short length.

Furthermore, the elastic pieces 6 extend in the left-right direction X from end portions of the fixed portions 4 that is on the opposite sides in the left-right direction X with respect to the sides on which the lateral pieces 5a are provided. With the above, a small-sized linear conductor connection terminal 1 can be provided while economically using a single piece of metal plate.

As described above, the present exemplary embodiment is capable of providing a small-sized linear conductor connection terminal 1. Furthermore, the present exemplary embodiment is capable of providing, with high work efficiency, a linear conductor connection terminal 1 with a high connection reliability.

### Second Exemplary Embodiment

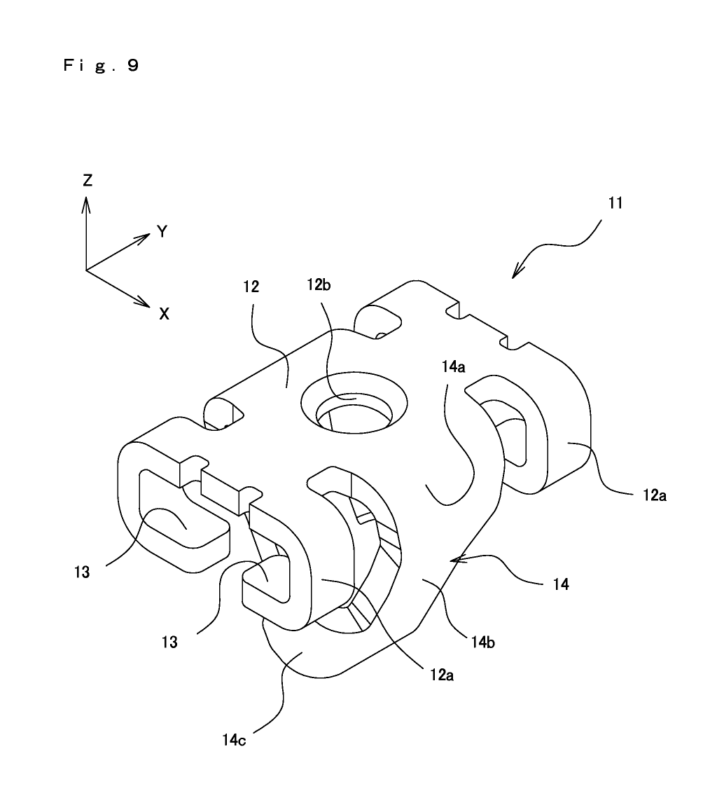

### FIGS. 9 to 16

In the present exemplary embodiment, the X direction is the short direction of a linear conductor connection terminal 11, and the Y direction corresponds to the longitudinal direction.

An example in which the top surface portion 5 of the linear conductor connection terminal 1 of the first exemplary embodiment described above includes the pair of lateral pieces 5a and the pair of front-rear pieces 5b has been given. Conversely, the linear conductor connection terminal 11 may include a top surface portion 12 formed of a single piece of metal plate. Furthermore, in the first exemplary embodiment described above, an example in which the elastic pieces 6 of the linear conductor connection terminal 1 extends from the fixed portions 4 has been given. Conversely, the elastic pieces 6 may extend from the top surface portion 12.

### Fixed Portion

As illustrated in FIGS. 9 to 13, fixed portions 13 and 13 are each formed at a portion that is on both end sides of the linear conductor connection terminal 11 in the left-right direction X and that is on both end sides in the front-rear direction Y. Accordingly, the linear conductor connection terminal 11 includes a total of four fixed portions 13. Furthermore, each of the fixed portions 13 includes a plate surface that is parallel to the substrate surface 3a and is formed of a rectangular metal plate extending in the left-right direction X. By fixing the fixed portions 13 by soldering, the linear conductor connection terminal 11 fixed to the substrate 3.

### Top Surface Portion

The top surface portion 12 is provided so as to be spaced apart from the substrate surface 3a and, as illustrated in FIGS. 9 to 13, is formed of a single piece of substantially rectangular metal piece and includes an insertion hole 12b.

A piece of leg portion 12a is connected to each of the four corners of the top surface portion 12. Each leg portion 12a extends in the height direction Z from the corresponding fixed portions 13, and the top surface portion 12 is supported with the leg portions 12a so as to be spaced apart from the substrate surface 3a.

The insertion hole 12b is formed at substantially the middle of the top surface portion 12 and is formed as a substantially circular through hole. Furthermore, the insertion hole 12b is provided above the hole portion 3b described later provided in the substrate 3.

The insertion hole 12b is formed with a size that allows the linear conductor 2a of the cable 2 to be inserted therethrough but does not allow the coating 2b to be inserted therein.

As described above, by forming the insertion hole 12b as the through hole provided in a single piece of metal plate that forms the top surface portion 12, the overall structure of the linear conductor connection terminal 11 can be further simplified and can be further reduced in size.

The top surface portion 12 is also supported with the leg portions 12a so as to be spaced apart from the contact portions 15 described later in the height direction Z. With the above, the insertion hole 12b and the contact portions 15 can be spaced apart from each other and an insertion passage 16 of the linear conductor 2a can be formed between the insertion hole 12b and the contact portions 15.

### Elastic Piece

Elastic pieces 14 each formed of a metal piece each extend from the corresponding one of the two end sides in the left-right direction X at a portion that is substantially the middle of the top surface portion 12 in the front-rear direction Y. As illustrated in FIGS. 9 to 13, 15, and 16, the elastic pieces 14 each includes a bend portion 14a, an inclination portion 14b, and a guide portion 14c.

Each bend portion 14a is connected to the top surface portion 12 and is formed so as to curve outwardly. With the elastic deformation of the bend portions 14a, the elastic pieces 14 as a whole can be elastically deformed.

Each inclination portion 14b is connected to the corresponding bend portion 14a and inclines in a downward direction in the height direction Z and in a direction that approaches the linear conductor 2a when the linear conductor 2a is inserted in the linear conductor connection terminal 11. Furthermore, the lower sides of the elastic pieces 14 are disposed below undersides 13a of the fixed portions 13.

Each guide portion 14c is provided as a metal piece on the distal end side of the corresponding elastic piece 14 so as to extend in the height direction Z and the left-right direction X. Each guide portion 14c is provided by bending one end side on the distal end side of the corresponding elastic piece 14 in the front-rear direction Y at substantially right angle. The guide portions 14c and 14c included in a first elastic piece 14A and a second elastic piece 14B that opposes each other are provided at different positions in the front-rear direction Y such that the guide portions 14c and 14c do not interfere with each other. Furthermore, the guide portion 14c and 14c oppose each other. The space between the guide portion 14c and 14c may have a size that allows the linear conductor 2a to pass therethrough.

### Contact Portion

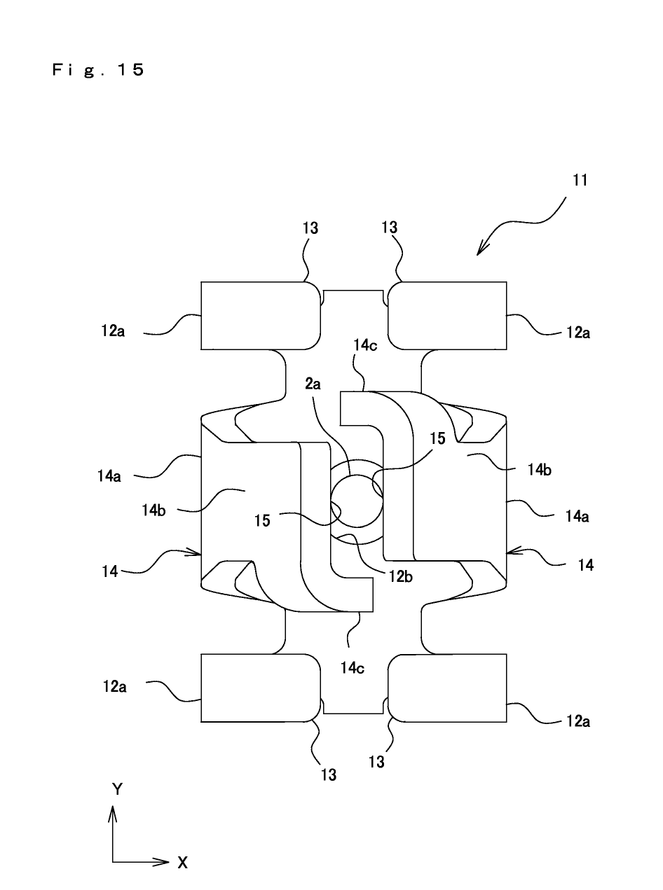

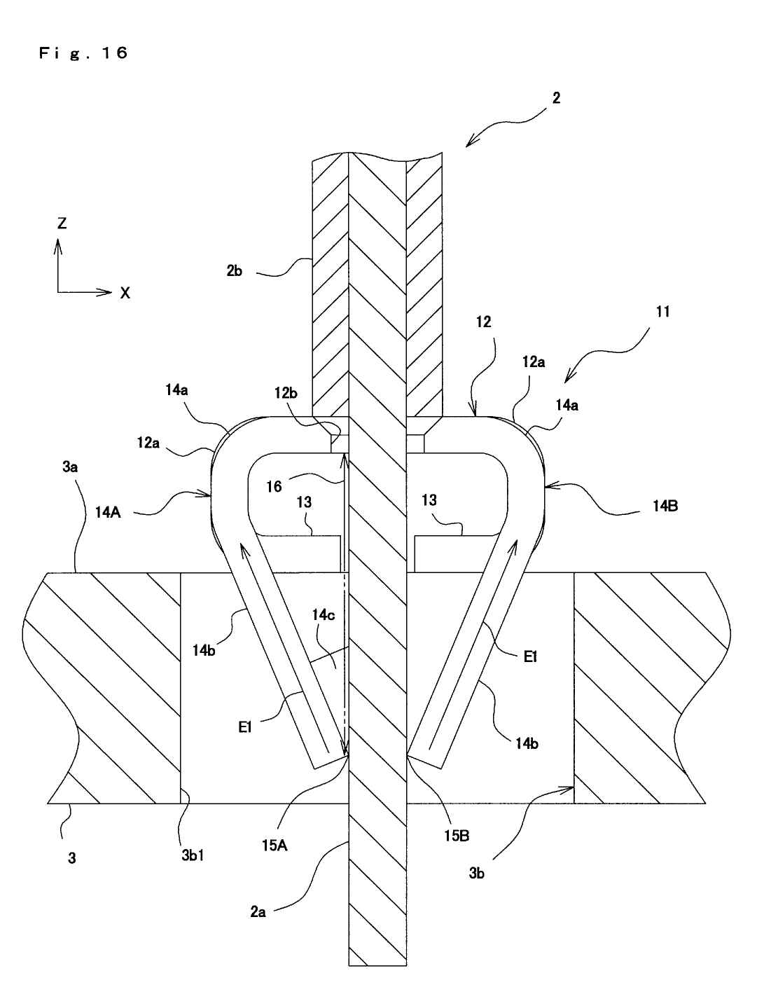

As illustrated in FIGS. 15 and 16, the contact portions 15 are provided on the distal end sides of the inclination portions 14b of the elastic pieces 14. Furthermore, the contact portions 15 are provided at edge portions of the distal end sides of the metal pieces that constitute the first elastic piece 14A and the second elastic piece 14B. The first contact portion 15A and the second contact portion 15B that are provided in the first elastic piece 14A and the second elastic piece 14B, respectively, oppose each other.

As described above, the distal end sides of the inclination portions 14b are disposed below the undersides 13a of the fixed portions 13 by a length of L4. Furthermore, the contact portions 15 that are provided on the distal end sides thereof are disposed below the undersides 13a of the fixed portions 13 by a length that is substantially the same as length L4. Moreover, the gap L2 between the first contact portion 15A and the second contact portion 15B that oppose each other is provided so as to be narrower than the diameter of the linear conductor 2a when the linear conductor 2a is not inserted in the linear conductor connection terminal 11.

The insertion passage 16 of the linear conductor 2a is formed between the gap L2 between the first contact portion 15A and the second contact portion 15B, and the insertion hole 12b.

### Description of Usage

As illustrated in FIG. 16, the hole portion 3b that penetrates through the substrate 3 in the plate thickness direction is provided in the substrate 3.

Furthermore, as described above, the contact portions 15 are disposed below the undersides 13a of the fixed portions 13 of the linear conductor connection terminal 11 by a length that is substantially the same as length L4. The contact portions 15 are disposed inside the hole portion 3b provided in the substrate 3 and, in this state, the fixed portions 13 are soldered to the substrate surface 3a of the substrate 3. With the above, the linear conductor connection terminal 11 can be fixed to the substrate surface 3a.

The linear conductor 2a of the cable 2 is inserted into the insertion hole 12b positioned above the contact portions 15 in the height direction Z. In doing so, the linear conductor 2a is passed through the guide portion 14c and 14c that oppose each other and that are provided in the first elastic piece 14A and the second elastic piece 14B, and is inserted downwards towards the gap L2 between the first contact portion 15A and the second contact portion 15B. By further inserting the linear conductor 2a towards the lower side in the height direction Z, the tip of the linear conductor 2a presses the first elastic piece 14A and the second elastic piece 14B towards the lower side. Accordingly, with elastic deformation of the bend portions 14a of the elastic pieces 14, the elastic pieces 14 as a whole are elastically deformed. With the above, the gap L2 between the opposing first contact portion 15A and the second contact portion 15B is pushed and widened to about the same size as the diameter of the linear conductor 2a and, accordingly, the gap L2 allows the linear conductor 2a to pass therethrough.

By stopping the insertion operation of the linear conductor 2a, the contact portions 15 formed on the edge portions of the metal pieces constituting the elastic pieces 14 bites into the linear conductor 2a. By having the first contact portion 15A and the second contact portion 15B opposing each other bite into, and press and pinch the linear conductor 2a from both sides, the linear conductor 2a, the first contact portion 15A, and the second contact portion 15B are conductively connected in a reliable manner. In the above state, the linear conductor 2a is maintained in an upright state with respect to the substrate 3. As described above, by conductively connecting the linear conductor 2a to the substrate 3 while the linear conductor 2a is in an upright state, the space occupied by the linear conductor 2a on the substrate surface 3a can be reduced. Therefore, even if there is a portion on which the components are mounted densely, the linear conductor 2a can be made to be in contact in a conductive manner with the substrate 3 in a readily manner.

Furthermore, as described above, the insertion hole 12b is provided with a size that allows the linear conductor 2a of the cable 2 to be inserted therethrough but does not allow the coating 2b to be inserted therein. Accordingly, even if the linear conductor 2a is inserted into the insertion hole 12b, the insertion is stopped when the coating 2b abuts against the upper side (the upper surface of the top surface portion 12) of the insertion hole 12b. By adjusting the length in which the linear conductor 2a is exposed from the coating 2b, the length in which the linear conductor 2a is inserted into the hole portion 3b of the substrate 3 can be adjusted.

After completion of the operation of having the linear conductor 2a be in contact with the linear conductor connection terminal 11 in a conductive manner, even if the cable 2 is pulled in the pulling-out direction, the contact portions 15 provided at the edge portions of the metal plates constituting the elastic pieces 14 bite into the linear conductor 2a. In the above manner, the linear conductor 2a can be reliably prevented from being pulled out.

As described above, without performing any soldering, by mere insertion of the linear conductor 2a into the insertion hole 12b, the linear conductor 2a can be made to be in contact with the contact portions 15 in a conductive manner and the work of conductively connecting the linear conductor 2a to the substrate 3 can be completed in a readily manner.

Note that the tip portion of the linear conductor 2a may protrude out from below the substrate 3 while the linear conductor 2a is in contact with the linear conductor connection terminal 11 in a conductive manner. The above can be achieved by having the length of the portion of the linear conductor 2a that is exposed from the distal end of the coating 2b to be longer than the length from the insertion hole 12b to the surface on the lower side of the substrate 3 while in a state in which the linear conductor connection terminal 11 is mounted on the substrate surface 3a. By increasing the length of the protrusion in the above manner, visual recognition of the completion of the operation having the linear conductor 2a be in contact with the linear conductor connection terminal 11 in a conductive manner can be facilitated. Furthermore, with the above, the length in which the tip of the linear conductor 2a protrudes downwards from the contact portions 15 can be made longer. Accordingly, prevention of the linear conductor 2a from being pulled out from the linear conductor connection terminal 11 can be facilitated and connection reliability can be increased.

### Achieving Both Reduction in Size and Connection Reliability

In the present exemplary embodiment, the plate thickness of the substrate 3 is about 1.2 mm and the diameter of the linear conductor 2a is about 0.5 mm. Furthermore, the length of the entire linear conductor connection terminal 11 in the left-right direction X is about 1.8 mm, the length in the front-rear direction Y is about 2.6 mm, and the height is about 1.8 mm. Accordingly, the linear conductor connection terminal 11 can be reduced to a size that is about the same as the amount of solder remaining on the substrate surface 3a when fixing the linear conductor 2a to the substrate 3 by soldering, for example. Furthermore, since in the present exemplary embodiment, the top surface portion 12 is formed of a single metal piece and the insertion hole 12b as a through hole is provide in the top surface portion 12, further reduction is size with respect to the linear conductor connection terminal 1 of the first exemplary embodiment is achieved.

A height from the undersides 13a of the fixed portions 13 to an upper portion of the insertion hole 12b (an upper end of the top surface portion 12), in other words, a length of a structure portion on the upper side that is disposed above the substrate surface 3a in the height direction Z is about 0.85 mm. Accordingly, the length of the structure portion on the upper side in the height direction Z is smaller than the plate thickness of the substrate 3. Furthermore, a length from the undersides 13a of the fixed portions 13 to the distal ends of the elastic pieces 14 in the height direction Z, in other words, a length L4 of a structure portion on a lower side in the height direction Z that protrudes downwards from the undersides 13a of the fixed portions 13 and that is inserted into the hole portion 3b of the substrate 3 is about 0.95 mm and is smaller than the plate thickness of the substrate 3.

By configuring the distance between the insertion hole 12b and the contact portions 15 to be about 1.8 mm, the linear conductor 2a can be held at two points that are sufficiently set apart from each other. With the above, it is possible to hold the linear conductor 2a in an upright state with respect to the substrate 3 without the linear conductor 2a collapsing in a direction parallel to the substrate 3. Accordingly, the area occupied by the linear conductor 2a on the substrate surface 3a can be made small.

The height of the entire linear conductor connection terminal 1 of the first exemplary embodiment is about 1.7 mm and the height of the entire linear conductor connection terminal 11 of the present exemplary embodiment is about 1.8 mm. Accordingly, there is not much difference between the two. Furthermore, while the distance between the insertion hole 5c and the contact portions 7 in the first exemplary embodiment is about 1.7 mm, the distance between the insertion hole 12b and the contact portions 15 of the present exemplary embodiment is about 1.8 mm; accordingly, there is not much difference. However, in the present exemplary embodiment, the length L4 of the structure portion on the lower side in the height direction Z is longer, and the contact portions 15 and the elastic pieces 14 are longer than those of the first exemplary embodiment such that the linear conductor 2a can be inserted about 0.95 mm into the hole portion 3b of the substrate 3. With the above, compared with the first exemplary embodiment, the contact portions 15 can be lowered further downwards with respect to the undersides 13a of the fixed portions 13. Accordingly, while having the insertion hole 12b and the contact portions 15 be sufficiently apart from each other, in the linear conductor connection terminal 11, the structure portion on the upper side that is disposed on the upper side of the substrate 3 can be reduced in size in the height direction Z.

Furthermore, similar to the linear conductor connection terminal 1 of the first exemplary embodiment, by having the contact portions 15 and the linear conductor 2a be in contact with each other inside the hole portion 3b in a conductive manner, the portion in contact can be protected by the inner wall 3b1 forming the hole portion 3b. Accordingly, the contact reliability of the linear conductor connection terminal 11 can be increased.

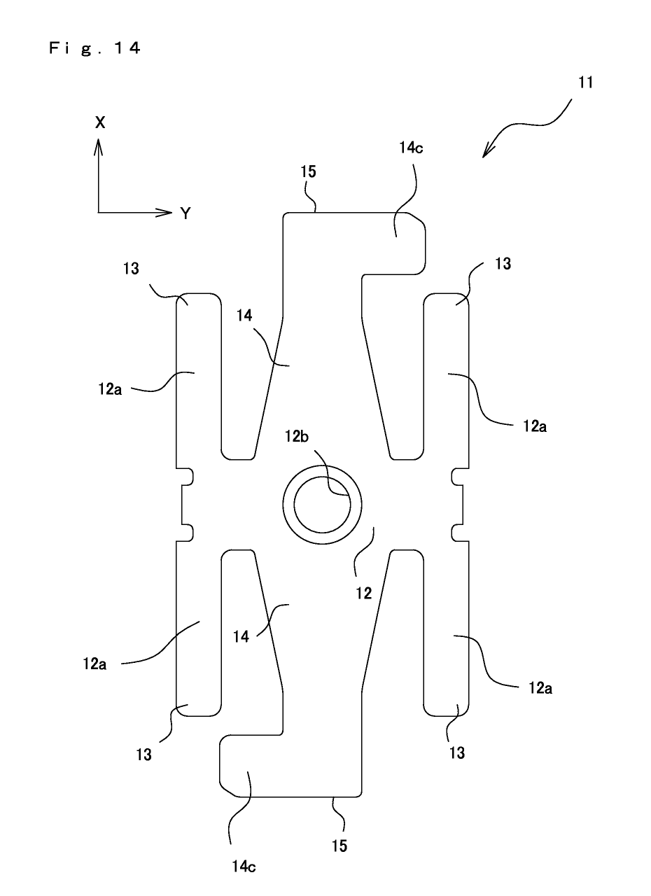

As illustrated in FIG. 14, when the linear conductor connection terminal 11 is expanded, the top surface portion 12 formed in a substantially rectangular manner is disposed at substantially the middle in the left-right direction X and extends in the front-rear direction Y. A single elastic piece 14 each extend in the front-rear direction Y from the corresponding one of the two sides of the top surface portion 12 in the front-rear direction Y at substantially the middle in the left-right direction X. As described above, the elastic pieces 14 being extended outwards from the top surface portion 12 when the linear conductor connection terminal 11 is in the expanded state allows the length of the elastic pieces 14 to be freely changed. Accordingly, by making the elastic pieces 14 longer, the elastic pieces 14 that are disposed inside the hole portion 3b of the substrate 3 can be made longer. With the above, by spacing the contact portions 15 and the insertion hole 12b sufficiently apart from each other, the linear conductor 2a can be held in a stable state at two points that are farther apart from each other. Furthermore, the linear conductor connection terminal 11 in which the structure portion on the upper side that is disposed on the upper side with respect to the substrate 3 is reduced in size in the height direction Z can be obtained. Design change of the length of the elastic pieces 14 can be freely made in accordance with the plate thickness of the substrate 3 and the length L4 inserted into the hole portion 3b.

Furthermore, different from the first exemplary embodiment, in the present exemplary embodiment, the elastic pieces 14 each include a single bend portion 14a. Each bend portion 14a has a shape extending towards the outside of the top surface portion 12 from a base portion that is on the top surface portion 12 side to the distal end side and, furthermore, extends in a direction coming in contact with the linear conductor 2a that has been inserted into the linear conductor connection terminal 11. Each bend portion 14a having such a shape has high rigidity especially against a force (indicated by arrows E1 in FIG. 16) that is obliquely applied thereto from the lower side to the upper side in a direction opposite to the direction of contact with the linear conductor 2a such that the bend portion 14a does not become deformed easily. Accordingly, even if a force is applied to the linear conductor 2a in a pulling-out direction and a load E1 is applied to each of the elastic pieces 14 from the linear conductor 2a, the bend portions 14a of the elastic pieces 14 do not become deformed easily. Accordingly, the linear conductor 2a can be surely prevented from being pulled out.

### Modification of Each Exemplary Embodiment

In each of the exemplary embodiments, examples have been given in which the tip of the linear conductor 2a protrudes below the substrate 3. Conversely, the tip of the linear conductor 2a may be disposed inside the hole portion 3b of the substrate 3.

In each of the exemplary embodiments, examples including the first contact portions 7A and 15A and the second contact portions 7B and 15B that oppose each other, respectively, have been given. Conversely, only either one of the first contact portion or the second contact portion may be provided. In such a case, for example, only the first contact portion 7A or 15A may be provided, and contact in a conductive manner may be achieved by pressing the linear conductor against the second elastic piece 6B or 14B so as to pinch the linear conductor. Furthermore, conversely, only the second contact portion 7B or 15B may be provided, and contact in a conductive manner may be achieved by pressing the linear conductor against the first elastic piece 6A or 14A so as to pinch the linear conductor.

What is claimed is:

1. A linear conductor connection terminal that is fixed to a substrate and that comes in contact in a conductive manner with a linear conductor that is inserted in a hole portion provided in the substrate; the linear conductor connection terminal comprising:
a contact portion that is positioned inside the hole portion and that comes in contact in the hole portion with the linear conductor in a conductive manner;
an elastic piece that elastically supports the contact portion;
a top surface portion provided so as to be spaced apart from the contact portion in an insertion direction of the linear conductor, the top surface portion including an insertion hole to introduce the linear conductor to the contact portion; and
a leg portion that supports the top surface portion that is spaced apart from the contact portion.

2. The linear conductor connection terminal according to claim 1, wherein
the contact portion includes a first contact portion and a second contact portion that oppose each other,
the elastic piece includes a first elastic piece that elastically supports the first contact portion, and a second elastic piece that elastically supports the second contact portion, and
the first contact portion and the second contact portion press and pinch the linear conductor that is inserted between the first contact portion and the second contact portion with spring force of the first elastic piece and the second elastic piece so as to be in contact with the linear conductor in a conductive manner.

3. The linear conductor connection terminal according to claim 1, wherein
the elastic piece includes a plate surface that extends in the insertion direction of the linear conductor and includes a guide portion that guides the linear conductor to the contact portion.

4. The linear conductor connection terminal according to claim 2, wherein
the elastic piece includes a plate surface that extends in the insertion direction of the linear conductor and includes a guide portion that guides the linear conductor to the contact portion.
